(19) United States
(12) Patent Application Publication
(10) Pub. No.: US 2023/0069961 A1
(43) Pub. Date: Mar. 9, 2023

(54) INFORMATION PROCESSING METHOD, INFORMATION PROCESSING SYSTEM, AND INFORMATION PROCESSING PROGRAM

(71) Applicant: Hitachi, Ltd., Tokyo (JP)

(72) Inventors: Tomochika TAKAMI, Tokyo (JP); Yuuichi SOEJIMA, Tokyo (JP)

(21) Appl. No.: 17/687,819

(22) Filed: Mar. 7, 2022

(30) Foreign Application Priority Data
Sep. 9, 2021 (JP) 2021-147128

(51) Int. Cl. H03M 7/30; G06F 17/16; H03M 7/40

(52) U.S. Cl. CPC H03M 7/6094; G06F 17/16; H03M 7/40

(57) ABSTRACT

The information processing system includes: a processing unit that executes processing in cooperation with a memory; and a storage unit that stores a compression technology for a data volume to be applied to a Hamiltonian of the optimization problem, a compressible condition indicating whether the compression technology can be applied or not, and compression method judgment information associated with a compression format indicating a feature quantity of the Hamiltonian when the Hamiltonian is compressed by applying the compression technology. The processing unit: refers to the compression method judgment information and judges a part included in the Hamiltonian which satisfies the compressible condition; and extracts the feature quantity of the part, which is included in the Hamiltonian and judged as satisfying the compressible condition, by means of the compression technology corresponding to the compressible condition and compresses the extracted feature quantity into the compression format.

### CROSS REFENCES TO RELATED APPLICATION

This application claims priority based on Japanese patent applications, No. 2021-147128 filed on Sep. 9, 2021, the entire contents of which are incorporated herein by reference.

### BACKGROUND

The present invention relates to an information processing method, an information processing system, and a non-transitory computer-readable recording medium for storing an information processing program.

Many of physical phenomena and social phenomena can be expressed by interaction models. An interaction model is defined by a plurality of nodes which constitute the mode, interactions between the nodes, and a coefficient(s) which acts on each node. Various models such as an Ising model are proposed in the fields of the physics and the social science, but any one of them is an aspect of the interaction models. Then, any problem of the physics, the social science, etc. can be replaced with a binary quadratic combinatorial optimization problem which finds a node status which minimizes or maximizes an index associated with the interaction model.

Regarding the binary quadratic combinatorial optimization problem, a set of constraint equations is described as, for example, a spin Hamiltonian in the Ising model. A constraint equation is, for example, an expression including variables called spins and a combination of spin values which minimizes the value of the constraint equation corresponds to a solution of the binary quadratic combinatorial optimization problem.The constraint equation is expressed as a quadratic Hamiltonian H as in, for example, H=(S₁+S₂+S₃+S₄+2)². In this expression, S₁, S₂, S₃, S₄ are spin variables and each of them takes the value of -1 or 1 (or 0 or 1). In this example of the constraint equation H, if one spin is 1 and each of the rest of the spins is -1, H becomes the minimum (= desired state (corresponding to the solution)).

Generally, the binary quadratic combinatorial optimization problem is solved by using a pseudo-annealing computer. If the constraint equation H for the problem handled by pseudo-annealing is described in a matrix, it is expressed as Expression (1). The pseudo-annealing computer inputs the problem expressed with a matrix (Jᵢⱼ) and a vector hᵢ as in Expression (1) and searches for σi which minimizes the Hamiltonian H. [Math. 1]

$$\begin{matrix}H = - {\sum }_{i < j} {J}_{i j} {σ}_{i} {σ}_{j} - {\sum }_{i} {h}_{i} {σ}_{i} \\ w h e r e {σ}_{i} ∈ \left\{- 1 , 1\right\} f o r ∀ i\end{matrix}$$

Accordingly, if the constraint equation for the binary quadratic combinatorial optimization problem is expressed as a matrix, it becomes an N order (square) matrix; and, therefore, when storing the constraint equation in a memory for the pseudo-annealing computer, assuming that one element of the matrix is n bytes, a memory capacity of n×N² bytes is required. Regarding this, there is proposed a technology that reduces the required memory capacity to store the constraint equation by compressing the matrix by using singular value decomposition and inner product calculation (for example, see PTL 1).

### CITATION LIST

### Patent Literature

PTL 1: Japanese Patent Application Laid-Open (Kokai) Publication No. 2017-142629

### SUMMARY

However, with the aforementioned conventional technology, when an input matrix is an N-order matrix, the memory capacity of N² order is still required and there is room for further reduction of the required capacity of the memory.

The present invention was devised in light of the above-described problem and it is one of objects to reduce the required capacity of the memory to store the constraint equation for the combinatorial optimization problem.

In order to solve the above-described problem, there is provided according to one aspect of the present invention an information processing method executed by an information processing system for executing an optimum solution search of an optimization problem, wherein the information processing system includes: a processing unit that executes processing in cooperation with a memory; and a storage unit that stores a compression technology for a data volume to be applied to a Hamiltonian of the optimization problem, a compressible condition indicating whether the compression technology can be applied or not, and compression method judgment information associated with a compression format indicating a feature quantity of the Hamiltonian when the Hamiltonian is compressed by applying the compression technology; and wherein the processing unit: refers to the compression method judgment information and judges a part included in the Hamiltonian which satisfies the compressible condition; and extracts the feature quantity of the part, which is included in the Hamiltonian and judged as satisfying the compressible condition, by means of the compression technology corresponding to the compressible condition and compresses the extracted feature quantity into the compression format.

According to the present invention, for example, the required capacity of the memory to store the constraint equation for the combinatorial optimization problem can be reduced.

The details of one or more implementations of the subject matter described in the specification are set forth in the accompanying drawings and the description below. Other features, aspects, and advantages of the subject matter will become apparent from the description, the drawings, and the claims.

### BRIEF DESCRIPTION OF DRAWINGS

FIG. 1 is a diagram for explaining an M-in-N-pieces selection problem;

FIG. 2 is a diagram for explaining an N-rook problem;

FIG. 3 is a diagram for explaining an N-cities traveling salesman problem;

FIG. 4 is a diagram for explaining Hamiltonian compression;

FIG. 5 is a diagram illustrating the configuration of the entire system according to Embodiment 1;

FIG. 6 is a diagram illustrating a first compression method judgment table according to Embodiment 1;

FIG. 7 is a diagram illustrating a second compression method judgment table according to Embodiment 1;

FIG. 8 is a diagram illustrating a variable group table according to Embodiment 1;

FIG. 9 is a diagram illustrating a divided information table according to Embodiment 1;

FIG. 10 is a flowchart illustrating the entire processing of Embodiment 1;

FIG. 11 is a flowchart illustrating former half processing of compression processing according to Embodiment 1;

FIG. 12 is a diagram illustrating input and output of the former half processing of the compression processing according to Embodiment 1;

FIG. 13 is a flowchart illustrating latter half processing of the compression processing according to Embodiment 1;

FIG. 14 is a diagram illustrating input and output of the latter half processing of the compression processing according to Embodiment 1;

FIG. 15 is a flowchart illustrating matrix calculation processing using a compression format of Embodiment 1;

FIG. 16 is a flowchart illustrating the entire processing of Embodiment 2;

FIG. 17 is a diagram illustrating a first compression method judgment table according to Embodiment 2;

FIG. 18 is a flowchart illustrating the entire processing of Embodiment 2;

FIG. 19 is a flowchart illustrating compression processing according to Embodiment 2;

FIG. 20 is a flowchart illustrating divided position deciding processing in the compression processing according to Embodiment 2;

FIG. 21 is a diagram for explaining matrix division according to Embodiment 2;

FIG. 22 is a diagram illustrating a configuration example of hardware of a computer for implementing the information processing system according to the embodiments.

### DESCRIPTION OF EMBODIMENTS

Embodiments of the present invention will be explained below with reference to the drawings. The embodiments including the drawings are merely for illustrative purposes for explaining the present invention and do not limit the present invention and some omissions and simplifications are made as necessary in order to clarify the explanation. The present invention can be also implemented in other various forms or in forms of combining some or all of the respective forms. Unless particularly restrained, each constituent element may be singular or plural.

If there are a plurality of constituent elements having the same function or similar functions, they may be sometimes explained by attaching different index to the same reference numeral. Also, if it is unnecessary to distinguish these plurality of constituent elements, they may sometimes be explained by omitting the index.

In the embodiments, information will be illustrated in a table format; however, the information is not limited to the table format and may be in other formats.

### Mathematical Background Regarding Embodiments

For example, if all coupling problems of nodes in pseudo-annealing are expressed with a matrix, all elements of the matrix are required. Depending on the problems, most of them become a sparse matrix in which the matrix elements are 0, so that the matrix can be compressed by using an arithmetic operation library for the sparse matrix. On the other hand, in a case of a dense matrix, the matrix cannot be compressed by a method similar to that of the sparse matrix. The compression of the matrix herein used does not mean to express the matrix by using its all elements, but to express the matrix by focusing on features of the matrix and with a smaller information volume than the case of using all the elements.

So, the embodiments disclosed by this application adopt a method for converting the Hamiltonian into a specified compression format and then inputting it to a pseudo-annealing computer. The method of converting the Hamiltonian into the specified compression format is closely related to designing of the Hamiltonian. Accordingly, since the specified compression format is decided according to the designing of the Hamiltonian, it is possible to directly calculate the specified compression format from the constraint equation of the Hamiltonian and to convert the Hamiltonian into the specified compression format through the matrix.

Furthermore, the pseudo-annealing computer includes a functional unit that executes calculation in response to input of the specified compression format.

Normally, a Hamiltonian H is described as an addition of a plurality of constraint equations. Each constraint equation is often described corresponding to a partial matrix of a matrix (Jᵢⱼ) of the Hamiltonian H. Furthermore, a plurality of kinds of “specific problems” are often used for the constraint equation(s). Furthermore, the number of parameters for describing the “specific problem” is often smaller than the number of matrix elements of the matrix (Jᵢⱼ).

Therefore, the used amount of the memory can be reduced by not decompressing the constraint equation to the matrix, but by replacing the constraint equation with parameters for the “specific problem” (or compression expressing parameters of the constraint) and retaining them in the memory. Furthermore, by preparing a calculation program corresponding to each “specific problem” in advance, it is possible to speed up the arithmetic operation processing depending on the type of the problem.

An explanation will be provided below about examples of a method for generating the specified compression format which is input information of the pseudo-annealing computer. Specific examples of the above-mentioned “specific problem” include an “M-in-N-pieces selection problem,” an “N-rook problem,” and a “traveling salesman problem.”

### M-in-N-Pieces Selection Problem

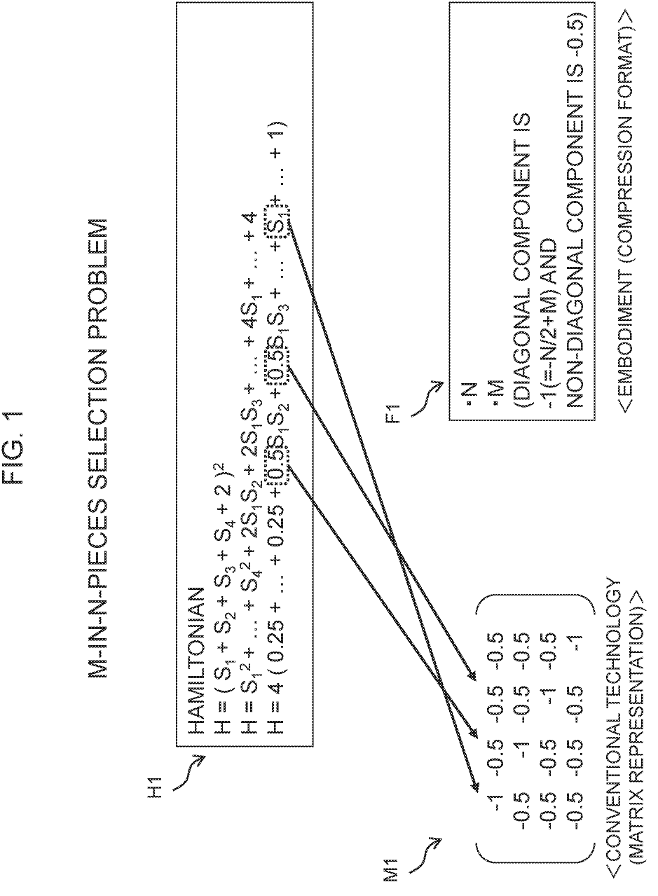

FIG. 1 is a diagram for explaining the M-in-N-pieces selection problem. For example, we will discuss a constraint equation to “select only one spin from four spins.” This constraint equation is expressed with a Hamiltonian H1 expressed in FIG. 1. Incidentally, transformation of the Hamiltonian H1 is Sᵢ∈{-1, -1} (i=1, 2, 3, 4) and Si²=1 is used.

According to the conventional technology, the Hamiltonian H1 is converted into a matrix M1 (FIG. 1) which has the respective terms, as elements, of the Hamiltonian H1 with inverting signs, and the matrix M1 is retained in the memory. When the number of the spin variables is N, the matrix M1 becomes an N-th order (square) matrix. Since N=4 is employed in the example in FIG. 1, the matrix becomes a 4^{th} order matrix and the number of elements (data quantity) becomes 16.

Meanwhile, all diagonal components of the matrix which represents the “M-in-N-pieces selection problem” to “select only M spins in N spins” become the same value (-N/2+M). Furthermore, all non-diagonal components become the same value (-0.5). Incidentally, the same applies to a case where the spin variable is Sᵢ∈{0, -1} (i=1, 2, 3, 4). Therefore, in the case of the “M-in-N-pieces selection problem,” a compression format F1 in which the number of elements M and N is 2 has information equivalent to the matrix M1. Incidentally, the diagonal component =-N/2+M and the non-diagonal component =-0.5 may be used as the compression format F1.

In this embodiment, in the case of the “M-in-N-pieces selection problem,” the value in each state of the Hamiltonian is calculated by using a calculation program corresponding to the “M-in-N-pieces selection problem” and applying the compression format F1 as input.

Consequently, the matrix calculation is executed based on the N-th order matrix according to the conventional technology, while in this embodiment, the matrix calculation is executed based on the compression format F1 in which the number of elements is 2. Specifically speaking, the calculation of an optimum value can be executed based on the compression format F1 with a smaller information volume than that of the conventional technology. So, it is possible to reduce the required capacity of the memory to store the Hamiltonian.

Incidentally, 99% or more of the matrix components may become 0 depending on the problem. Calculation time is the same regardless of values of the matrix components by the calculation method of the conventional technology; however, in the case of the embodiments, it is possible to speed up the processing by omitting most parts of the calculation for such a problem.

### N-Rook Problem

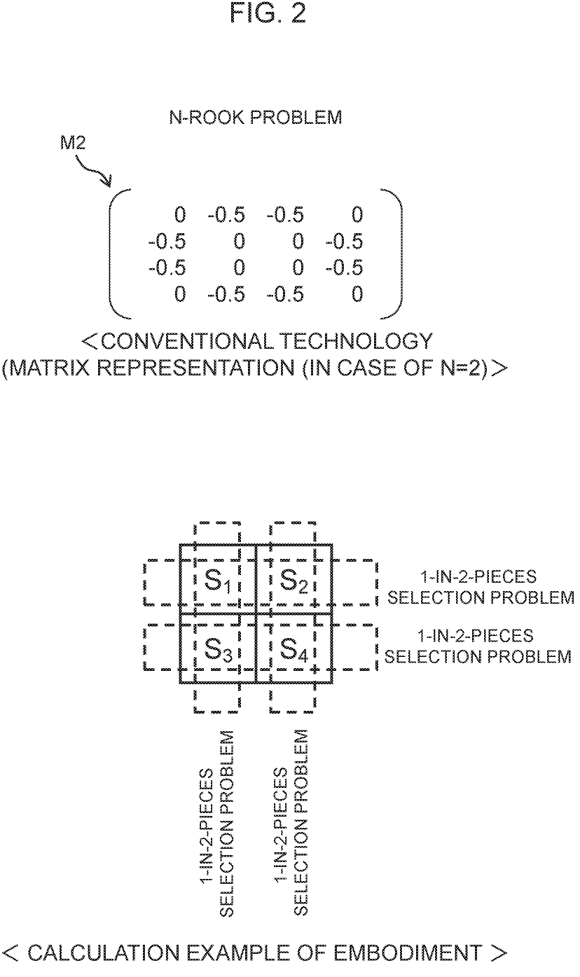

FIG. 2 is a diagram for explaining an N-rook problem.

The fact that the problem is the “N-rook problem” is judged as the problem is set as the “N-rook problem” or is judged by a specified judgment algorithm.

An explanation will be provided about an example where the problem is judged as being the “N-rook problem” by the specified judgment algorithm. The “N-rook problem” can be solved by using a calculation program corresponding to the “N-rook problem” and using the coordinates Sᵢ=(xᵢ, yᵢ) (i=1, 2, ..., N) of each spin in N×N matrix squares as input.

An explanation will be provided about an example where a “partial matrix with a specific pattern” of an N-th order (N<n) of an n-th order matrix in which coefficients of the respective terms of the quadratic constraint equation of the Hamiltonian representing the problem are aligned in accordance with a specified rule.

The “partial matrix with a specific pattern” herein used is a specific partial matrix from which (n-N) rows/columns are excluded respectively from rows and columns of the n-th order matrix. A matrix M2 illustrated in FIG. 2 is an example of n=4, N=2; and any one of the following “partial matrixes with a specific pattern” becomes a matrix which represents a “1-in-2-pieces selection problem” where the diagonal component is 0 and the non-diagonal component is -0.5: a “second order matrix obtained by excluding the 3^{rd} row, the 4^{th} row, the 3^{rd} column, and the 4^{th} column from the matrix M2”; a “second order matrix obtained by excluding the 1^{st} row, the 2^{nd} row, the 1^{st} column, and the 2^{nd} column from the matrix M2”; a “second order matrix obtained by excluding the 2^{nd} row, the 4^{th} row, the 2^{nd} column, and the 4^{th} column from the matrix M2”; and a “second order matrix obtained by excluding the 1^{st} row, the 3^{rd} row, the 1^{st} column, and the 3^{rd} column from the matrix M2.”

Generally with the “N-rook problem,” N pieces of rooks are placed in the N×N matrix squares in the state of mutually having no power of move. Spins S₁, S₂, ..., S_{N}, S_{N+1}, ..., S_{N×N} are allocated to the respective N×N matrix squares. In this case, each of N×N combinations of the spins {S₁, S₂, ..., S_{N}}, {S_{N+1}, S_{N+2}, ..., S_{2N}}, ..., {S_{(N-1)xN+1}, S_{(N-} _{1)xN+2}, ..., S_{N×N}}, {S₁, S_{N+1}, ..., S_{(N-1)×N+1}}, {S₂, S_{N+2}, ..., S_{(N-1)×N+2}}, ..., {S_{N}, S_{2N}, ..., S_{N×N}} represents a “one-in-N-pieces selection problem.” In an example illustrated in the lower part of FIG. 2, N=2 is employed, spins S₁, S₂, S₃, S₄ are allocated to 2×2 matrix squares, each of 2×2 combinations of the spins {S₁, S₂}, {S₃, S₄}, {S₁, S₃}, {S₂, S₄} becomes the “1-in-2-pieces selection problem.”

Contrarily, if it is judged by the specified judgment program that a set of N-th order partial matrixes of the n-th order matrix which represents the quadratic constraint equation of the Hamiltonian which is the problem include all the matrixes which represent the “1-in-N-pieces selection problem” by the respective combinations of the spins {S₁, S₂, ..., S_{N}}, {S_{N+1}, S_{N+2}, ..., S_{2N}}, ..., {S_{(N-1)×N+1}, S_{(N-1)×N+2}, ..., S_{N×N}}, {S₁, S_{N+1}, ..., S(_{N-1)×N+1}}, {S₂, S_{N+2}, ..., S(_{N-1)×N+2}}, ..., {S_{N}, S_{2N}, ..., S_{N×N}}, it can be judged that the problem represented by this n-order matrix can be solved as the “N-rook problem”.

Accordingly, the “N-rook problem” can be judged as being the “N-rook problem” by focusing on the coefficient of the quadratic term in the quadratic constraint equation of the Hamiltonian in the same manner as an “N-in-N-pieces selection problem” and also can be judged as being the “N-rook problem” by focusing on the matrix elements of the Hamiltonian.

Therefore, if the problem is the “N-rook problem,” it can be said that the compression format of the number of elements 3N for the “coordinates Sᵢ=(xᵢ, yᵢ) of each spin in the N×N matrix squares” is information equivalent to the matrix M2.

In the embodiments, in the case of the “N-rook problem,” the problem is solved by using the calculation program corresponding to the “N-rook problem” and applying the “coordinates Sᵢ=(xᵢ, yᵢ) of each spin in the N×N matrix squares” as input.

Consequently, regarding the “N-rook problem” as well, the optimum value calculation can be executed based on the compression format with a smaller information volume than that of the matrix and the required capacity of the memory to store the Hamiltonian which is the problem can be reduced.

### N-Cities Traveling Salesman Problem

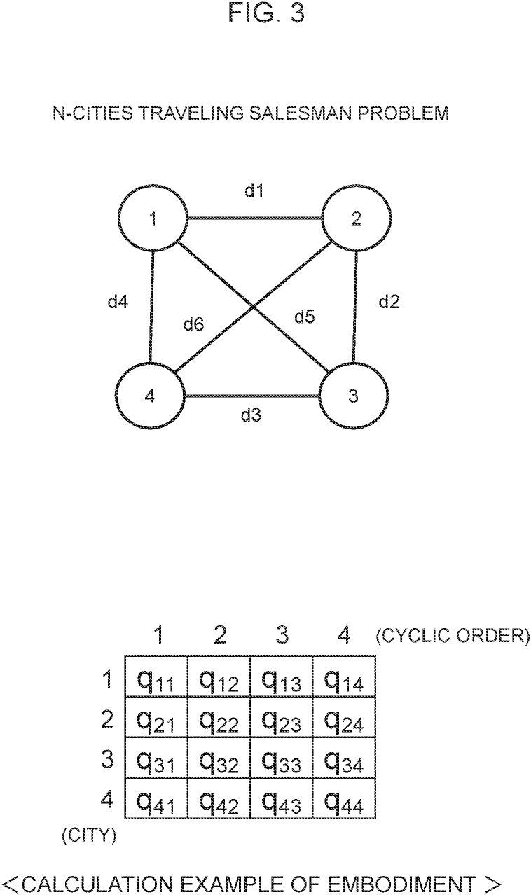

FIG. 3 is a diagram for explaining an N-cities traveling salesman problem.

The fact that the problem is the “N-cities traveling salesman problem” is judged as the problem is set as the “N-cities traveling salesman problem” or is judged by a specified judgment algorithm.

The “N-cities traveling salesman problem” is a problem to optimize a cyclic order of the respective N cities in consideration of the following constraint conditions: “each of N cities can be visited only once,” “a plurality of cities cannot be visited at the same time,” and “the distance between the respective cities should be considered.” FIG. 3 shows a graph of a “4-cities traveling salesman problem” in a case of N=4, where nodes 1 to 4 correspond to the cities and d₁ to d₆ assigned to an edge(s) between the nodes is the distance between the respective nodes.

The two constraints “each of N cities can be visited only once” and “a plurality of cities cannot be visited at the same time” among the constraints of the “N-cities traveling salesman problem” can be described according to the “N-rook problem.”

The “N-cities traveling salesman problem” can be expressed by further adding the constraint condition of “the distance between the respective cities should be considered” to the “N-rook problem.” The distance between the respective cities is generally irregular, so that it is difficult to compress it by using a constraint equation or a matrix; however, the information of the distance between the cities is compressible by expressing each city with coordinates.

Accordingly, the “N-cities traveling salesman problem” can be also judged as being the “N-cities traveling salesman problem” by focusing on the coefficient of the quadratic term in the quadratic constraint equation of the Hamiltonian in the same manner as an “N-in-N-pieces selection problem” and the “N-rook problem” and also can be judged as being the “N-cities traveling salesman problem” by focusing on the matrix elements of the Hamiltonian.

However, when compressing the “N-cities traveling salesman problem” by adding the information of the distance between the cities to the “N-rook problem,” the compression effect of the information is obtained in a case of N≥6.

In the embodiments, in the case of the "N-cities traveling salesman problem" as illustrated in the drawing in the lower part of FIG. 3, the value of a variable qᵢⱼ is calculated by defining the variable qᵢⱼ and using the calculation program corresponding to the "N-cities traveling salesman problem" and applying the respective coordinates Zᵢ=(xᵢ, yᵢ)" (i=1, 2, ..., N) (data quantity is 2N) of the respective N cities. The variable qᵢⱼ takes, for example, the value of 1 when the city i is visited for the j-th time, and the value of 0 for other cases. It is assumed that the “N-cities traveling salesman problem” is set manually, but it may be set mechanically by a computer.

In the embodiments, in the case of the “N-cities traveling salesman problem,” the problem is solved by using the calculation program corresponding to the “N-cities traveling salesman problem” and applying the “coordinates Zᵢ=(xᵢ, yᵢ) of all the N cities” (i=1, 2, ..., N) as input.

Consequently, regarding the “N-cities traveling salesman problem” as well, the optimum value calculation can be executed based on the compression format with a smaller information volume than that of the matrix and the required capacity of the memory to store the Hamiltonian which is the problem can be reduced.

Generally, if a real problem is directly formed into a matrix, the relationship between the real problem and known specific problems (such as the “M-in-N-pieces selection problem,” the “N-rook problem,” and the “N-cities traveling salesman problem”) can hardly be seen. The embodiments are designed to examine the relationship between the real problem and the known “specific problems” and recognize the real problem as a combination of the “known problems,” thereby making it easier to find the features of the constraint equation or the matrix of the Hamiltonian which represents the real problem and compressing its information volume.

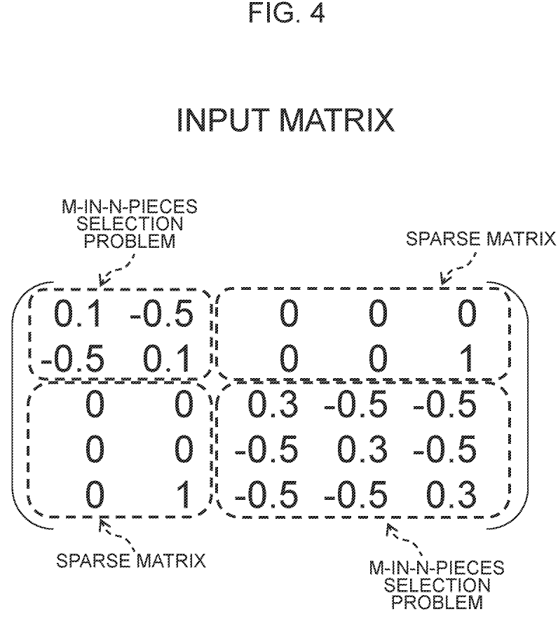

FIG. 4 is a diagram for explaining the compression of the Hamiltonian.

The problem which is actually given to the pseudo-annealing is not simple as the M-inN-pieces selection problem and various elements are included in the Hamiltonian. So, as illustrated in FIG. 4, the input matrix which represents the Hamiltonian (or the matrix which has coefficients of the quadratic constraint equation of the Hamiltonian as elements) is divided into a plurality of areas by matrix division, and whether each area corresponds to any one of the “specific problems” (the “M-in-N-pieces selection problem,” the “N-rook problem,” and the “N-cities traveling salesman problem”) or a “specific area” (such as a “zero matrix,” a “constant matrix,” a “sparse matrix,” and a “transposed matrix”) is judged.

Since a division pattern of the matrix into a plurality of areas depends on a spin allocation method (for example, for selecting one spin from a plurality of spins), it is decided at the time of the creation of the constraint equation. The division of the matrix to the plurality of areas can be executed by program processing. Specifically speaking, the Hamiltonian can be directly divided into the plurality of areas of a matrix by using the program processing. Then, if the plurality of areas of the matrix correspond to the “specific problem” or the “specific area,” data can be compressed in the corresponding compression format.

It is known that if there are several patterns of the compression method (known specific problem), they can be practically applied to 80% or more of real problems. Therefore, by adopting the compression method according to the embodiments, it is possible to reduce the required capacity of the memory and shorten calculation processing time depending on the types of the real problems.

Incidentally, in the embodiments, an explanation will be provided about conversion of the Hamiltonian constraint equation into the compression format by likening it to a matrix to make it easier to understand. However, in fact, there are both the case where the Hamiltonian constraint equation is directly converted into the compression format without converting it to the matrix and by focusing on a coefficient of each term, and the case where the matrix of the Hamiltonian constraint equation is directly converted into the compression format.

### Embodiment 1

An explanation will be provided below about Embodiment 1 in which the Hamiltonian constraint equation is converted into the compression format, thereby expressing the Hamiltonian with a smaller information volume than that of the matrix and reducing the memory capacity to store the information.

### Configuration of Entire System 1 According to Embodiment 1

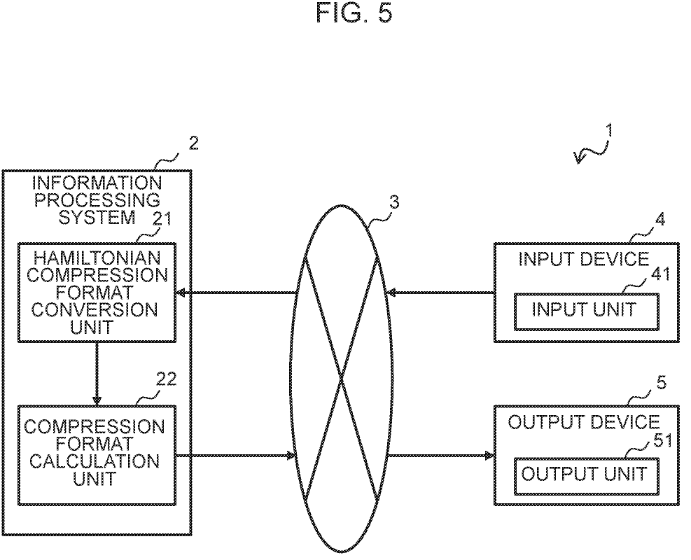

FIG. 5 is a diagram illustrating a configuration example of the entire system 1 according to Embodiment 1. The entire system 1 is configured by including an information processing system 2, an input device 4, and an output device 5 which are connected via a network 3 which is a public network or a closed network so that they can communicate with each other. The input device 4 includes an input unit 41 such as a keyboard for accepting user inputs and an output unit (which is not illustrated in the drawing) such as a display. The output device 5 includes an output unit 51 such as a display. The input device 4 and the output device 5 may be either the same device or separate devices.

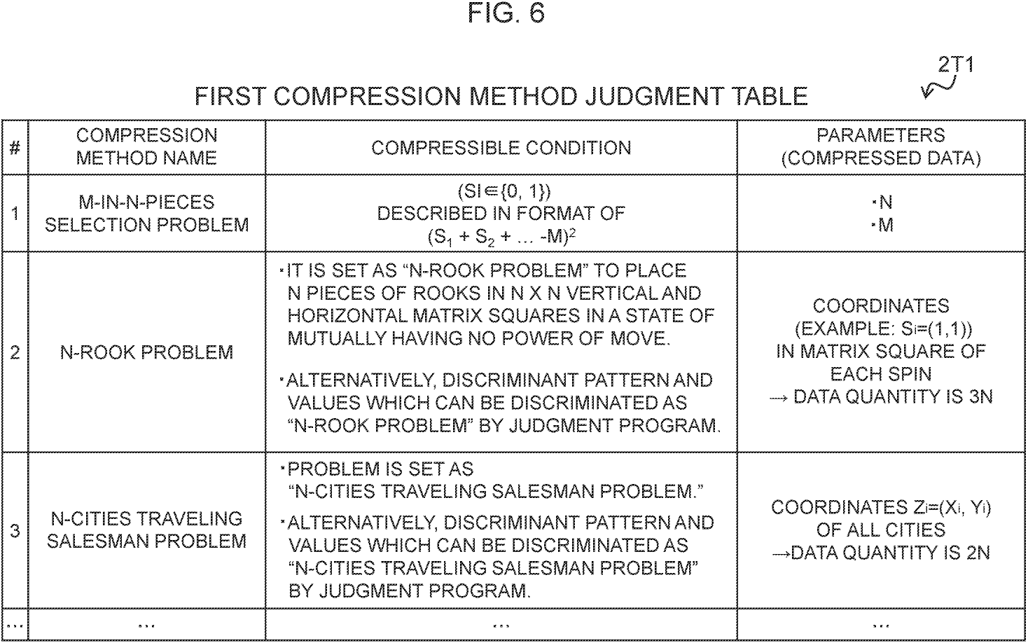

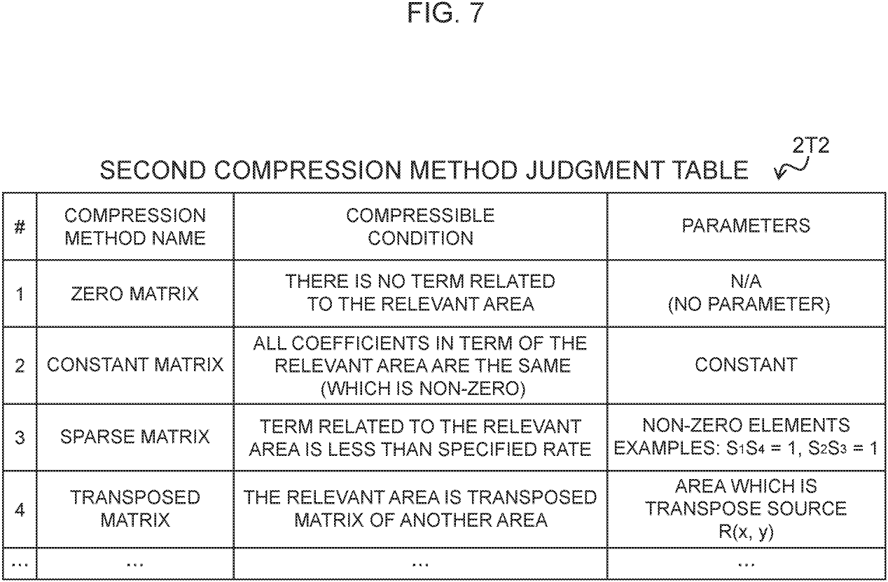

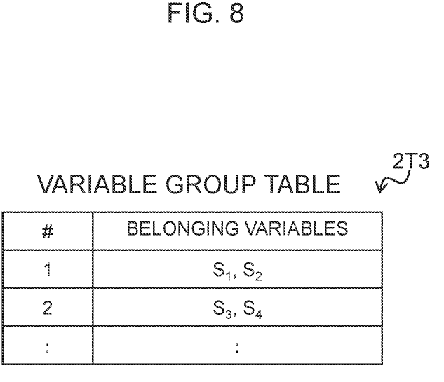

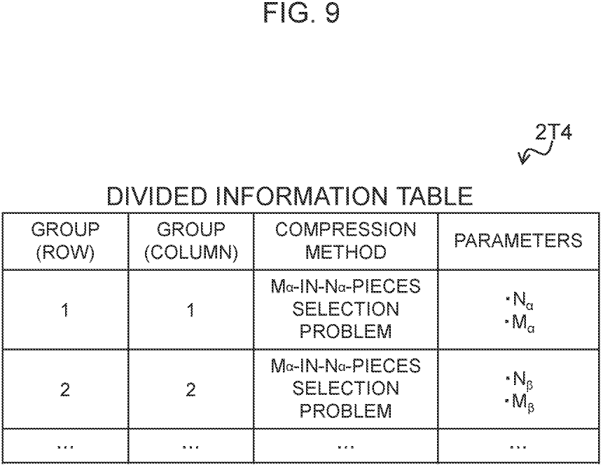

The information processing system 2 is a cloud or on-premises computer for executing pseudo-annealing based on the input information. The information processing system 2 includes a Hamiltonian compression format conversion unit 21 and a compression format calculation unit 22. Furthermore, the information processing system 2 retains a first compression method judgment table 2T1 (FIG. 6), a second compression method judgment table 2T2 (FIG. 7), a variable group table 2T3 (FIG. 8), and a divided information table 2T4 (FIG. 9) in a specified storage area (which is not illustrated in the drawing).

When compressing the Hamiltonian which has been input via the input unit 41 for the input device 4, the Hamiltonian compression format conversion unit 21 judges the compression method by referring to the first compression method judgment table 2T1 and the second compression method judgment table 2T2. Then, the Hamiltonian compression format conversion unit 21 converts the Hamiltonian into the compression format (compressed data) in accordance with the judged compression method. The details of the processing of the Hamiltonian compression format conversion unit 21 will be described later.

The compression format calculation unit 22 performs an arithmetic operation based on the compression format converted by the Hamiltonian compression format conversion unit 21. The compression format calculation unit 22 transmits the arithmetic operation result to the output device 5 so as to output it from the output unit 51. The details of the compression format calculation unit 22 will be described later.

### Various Kinds of Tables Possessed by Information Processing System 2 According to Embodiment 1

FIG. 6 to FIG. 9 are diagrams illustrating various kinds of tables possessed by the information processing system 2 according to Embodiment 1. The information processing system 2 retains the first compression method judgment table 2T1 (FIG. 6), the second compression method judgment table 2T2 (FIG. 7), the variable group table 2T3(FIG. 8), and the divided information table 2T4 (FIG. 9) in the specified storage area (which is not illustrated in the drawing).

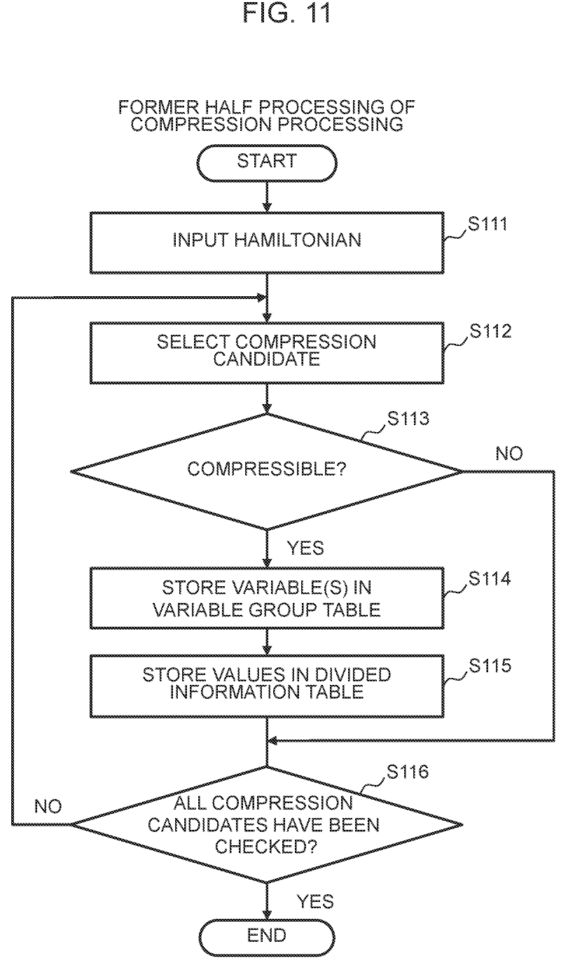

The first compression method judgment table 2T1 (FIG. 6) is a table for judging the compression method for the input Hamiltonian and has columns of a compression method name, a compressible condition, and parameters. When the Hamiltonian compression format conversion unit 21 (FIG. 5) executes the former half processing of the compression processing (FIG. 11) described later, it refers to the first compression method judgment table 2T1, extracts a feature quantity from the input Hamiltonian, and performs the compression into parameters (compressed data) of the compression method corresponding to the relevant compressible condition on the basis of the feature quantity.

For example, if the Hamiltonian compression format conversion unit 21 judges that the input Hamiltonian includes an area described in a format of (S₁+S₂+...-M) (Sᵢ is a spin which is 0 or 1), it recognizes, from the entry #1 of the first compression method judgment table 2T1, that this area corresponds to the compression method name “M-in-N-pieces selection problem.” If Sᵢ is a spin which is -1 or 1, the Hamiltonian compression format conversion unit 21 judges whether the input Hamiltonian includes an area described in a format of (S₁+S₂+...+M)². The “area” used herein means a polynomial including a quadratic term as at least a part of the input Hamiltonian. Then, the Hamiltonian compression format conversion unit 21 compresses the relevant area of the input Hamiltonian into parameters “N and M.” Incidentally, the compression parameters may be set as the diagonal component =-N/2+M and the non-diagonal component =-0.5.

Furthermore, for example, if the Hamiltonian compression format conversion unit 21 judges that the input Hamiltonian includes an area corresponding to the “N-rook problem,” it compresses the relevant area of the input Hamiltonian into coordinates of each spin Sᵢ=(xᵢ, yᵢ) (i=1, 2, ..., N×N) in N×N matrix squares. If the input Hamiltonian includes an area which is set as the “N-rook problem” or if it is judged by the judgment program that a pattern and value of a discriminant correspond to the “N-rook problem,” the relevant area is compressed into the parameters for the “N-rook problem.”

Furthermore, for example, if the Hamiltonian compression format conversion unit 21 judges that the input Hamiltonian includes an area corresponding to the “N-cities traveling salesman problem,” it compresses the relevant area of the input Hamiltonian into coordinates Zᵢ=(Xᵢ, Yᵢ) (i=1, 2, ..., N) of all the N cities. If the input Hamiltonian includes an area which is set as the “N-cities traveling salesman problem” or if it is judged by the judgment program that the pattern and value of the discriminant correspond to the “N-cities traveling salesman problem,” the relevant area is compressed to parameters for the “N-cities traveling salesman problem.”

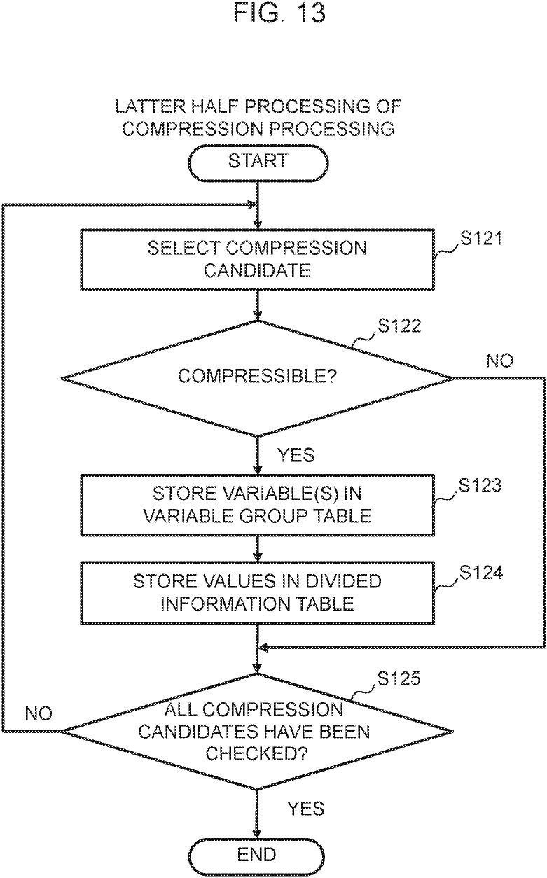

The second compression method judgment table 2T2 (FIG. 7) is a table for judging the compression method for the relevant area by targeting at an area(s) other than the area(s) compressed by the first compression method judgment table 2T1 (FIG. 6), in the input Hamiltonian. The second compression method judgment table 2T2 has columns of a compression method name, a compressible condition, and parameters. When executing the latter half processing of the compression processing (FIG. 13) described later, the Hamiltonian compression format conversion unit 21 refers to the second compression method judgment table 2T2, extracts a feature quantity from the input Hamiltonian, and performs the compression into the parameters (compressed data) for the compression method corresponding to the relevant compressible condition on the basis of the feature quantity.

For example, if the Hamiltonian compression format conversion unit 21 judges that there is no term in the relevant area of the input Hamiltonian, it recognizes, from the entry #1 of the second compression method judgment table 2T2, that this area corresponds to the compression method name “zero matrix.” Then, the Hamiltonian compression format conversion unit 21 compresses the relevant area of the input Hamiltonian into “no parameter (N/A).”

Moreover, for example, if the Hamiltonian compression format conversion unit 21 judges that coefficients of terms in the relevant area of the input Hamiltonian have the same non-zero value, it recognizes, from the entry #2 of the second compression method judgment table 2T2, that this area corresponds to the compression method name “constant matrix.” Then, the Hamiltonian compression format conversion unit 21 compresses the relevant area of the input Hamiltonian into the “constant” included in that area.

Also, for example, if the Hamiltonian compression format conversion unit 21 judges that the number of non-zero terms in the relevant area of the input Hamiltonian is less than a specified rate (for example, ⅓), it recognizes, from the entry #3 of the second compression method judgment table 2T2, that this area corresponds to the compression method name “sparse matrix.” Then, the Hamiltonian compression format conversion unit 21 compresses the relevant area of the input Hamiltonian into “non-zero element(s)” included in that area.

Furthermore, for example, if the Hamiltonian compression format conversion unit 21 judges that the relevant area of the input Hamiltonian is a transposed matrix of another area, it recognizes, from the entry #4 of the second compression method judgment table 2T2, that the area corresponds to the compression method name “transposed matrix.” Then, the Hamiltonian compression format conversion unit 21 compresses the relevant area of the input Hamiltonian into information R(x, y) capable of identifying an area which becomes a transpose source.

The variable group table 2T3 (FIG. 8) is a table which records variables (spins) included in each block when the matrix which represents the input Hamiltonian is divided into blocks.

The divided information table 2T4 (FIG. 9) is a table which records the compression method and the parameters for each block when the matrix which represents the input Hamiltonian is divided into blocks. For example, regarding a block specified with group #1 in the row direction and group #1 in the column direction, among the blocks obtained by dividing the matrix including the input Hamiltonian, its compression method is the “M_{α}-in-N_{α}-pieces selection problem” and its parameters are “N_{α}: 2, M_{α}: 1.”

### Entire Processing of Embodiment 1

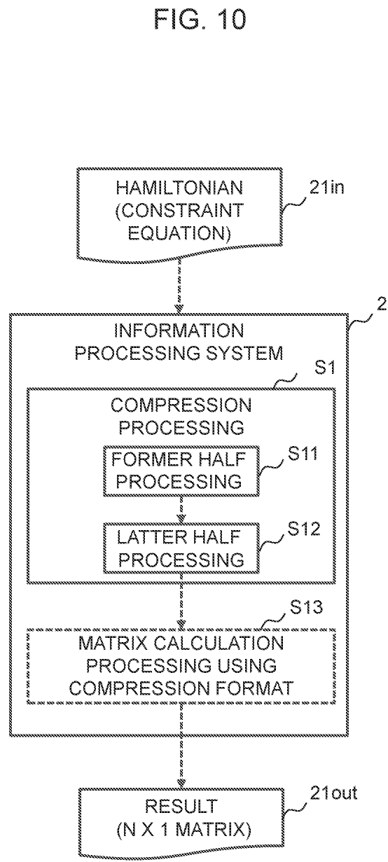

FIG. 10 is a flowchart illustrating the entire processing of Embodiment 1. Referring to FIG. 10, the information processing system 2 inputs a Hamiltonian (constraint equation) 21 in and outputs the result (N_{×}1 matrix) 21 out. The Hamiltonian compression format conversion unit 21 (FIG. 5) for the information processing system 2 converts an area of at least a part of the Hamiltonian (constraint equation) 21in into a compression format (compressed data) such as the “M-in-N-pieces selection problem,” the “N-rook problem,” or the “N-cities traveling salesman problem” in the former half processing (step S11) of the compression processing in step S1. The details of the former half processing will be described later.

Furthermore, in the latter half processing (step S12) following step S11, the Hamiltonian compression format conversion unit 21 converts an area(s) other than the area which was converted into the compression format such as the “M-in-N-pieces selection problem,” the “N-rook problem,” or the “N-cities traveling salesman problem” in the former half processing, into a compression format such as the “zero matrix,” the “constant matrix,” the “sparse matrix,” or the “transposed matrix.” The details of the latter half processing will be described later.

In step S13, the compression format calculation unit 22 (FIG. 5) executes matrix calculation processing using the compression formats obtained by the conversions in step S11 and S12. The details of the matrix calculation processing using the compression formats will be described later.

### Former Half Processing of Compression Processing According to Embodiment 1

FIG. 11 is a flowchart illustrating the former half processing of the compression processing according to Embodiment 1. This flowchart illustrates a procedure for converting the constraint equation into the compression format corresponding to the “specific problem.” The former half processing of the compression processing is executed by the information processing system 2 as triggered by the input of the Hamiltonian by the user.

It is assumed as a precondition that the Hamiltonian is described with a quadratic expression. In a case of a constraint equation of a cubic or any higher degree, a constraint equation of lowered degree obtained by lowering the degree to a quadratic expression by adding spins by a well-known method is set as a processing target. If the constraint equation is a linear expression or of lower degree, the solution will be found without the necessity of executing annealing and, therefore, it will be excluded from the processing target.

Firstly in step S111, the Hamiltonian compression format conversion unit 21 accepts the input of the Hamiltonian (constraint equation) 21 in. Next in step S112, the Hamiltonian compression format conversion unit 21 selects one of compression candidates for the Hamiltonian (constraint equation) 21 in. The compression candidate(s) is a polynomial composed of at least some terms of the Hamiltonian. For example, a term may be selected as the compression candidate sequentially on a term basis, starting from the top term of the Hamiltonian.

Subsequently in step S113, the Hamiltonian compression format conversion unit 21 refers to the first compression method judgment table 2T1 and judges whether the compression candidate selected in step S112 is compressible or not, that is, whether it corresponds to any one of the compressible conditions in the first compression method judgment table 2T1 or not. If the compression candidate is compressible (step S113: YES), the Hamiltonian compression format conversion unit 21 proceeds to processing in step S114; and if the compression candidate is not compressible (step S113: NO), the Hamiltonian compression format conversion unit 21 proceeds to processing in step S116. If the compression candidate selected in step S112 matches the plurality of compressible conditions in the first compression method judgment table 2T1, a specified selection rule, for example, to prioritize an entry close to the top of the first compression method judgment table 2T1 is set so that one compression method will be selected.

In step S114, the Hamiltonian compression format conversion unit 21 stores a variable(s) (spin(s)) included in the compression candidate, which is judged as being compressible in step S113, in the variable group table 2T3. Incidentally, it is assumed that the variables included in a plurality of compression candidates which are judged as being compressible in step S113 belong to an independent variable group.

Next, in step S115, the Hamiltonian compression format conversion unit 21 stores the compression method and parameters corresponding to the compressible condition of the compression candidate, which was judged as being compressible in step S113 in the first compression method judgment table 2T1, in the divided information table 2T4.

Then, in step S116, the Hamiltonian compression format conversion unit 21 judges whether all the compression candidates have been checked or not. If all the compression candidates have been checked (step S116: YES), the Hamiltonian compression format conversion unit 21 terminates this former half processing; and if any unchecked compression candidate exists (step S116: NO), the Hamiltonian compression format conversion unit 21 returns to the processing in step S112.

### Input and Output of Former Half Processing of Compression Processing According to Embodiment 1

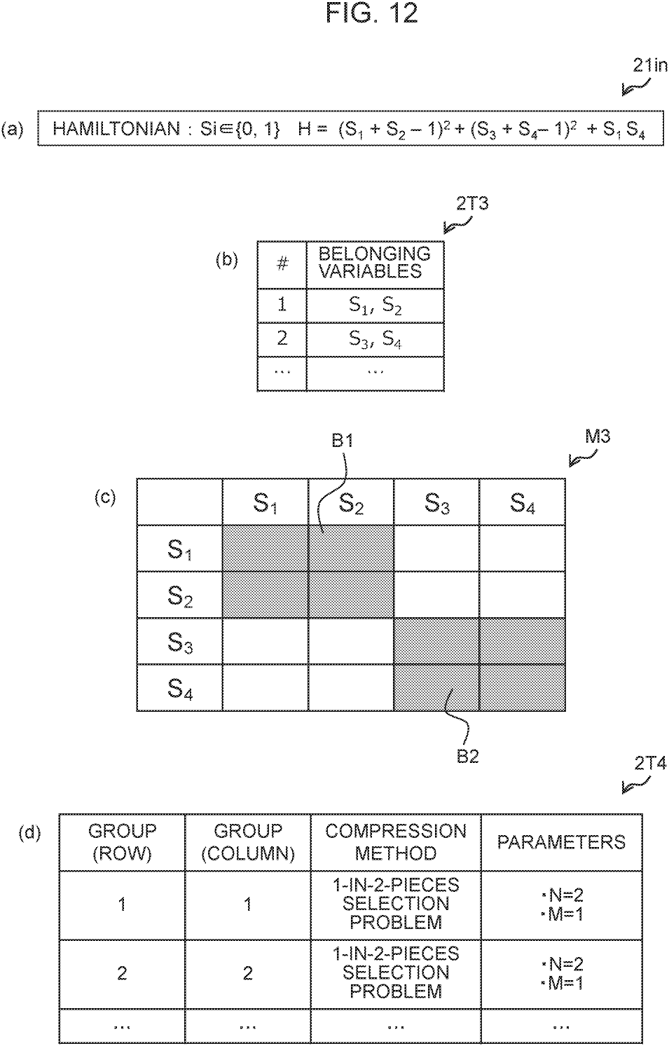

FIG. 12 is a diagram illustrating input and output of the former half processing of the compression processing according to Embodiment 1. For example, let us assume that the Hamiltonian (constraint equation) 21in is a polynomial as illustrated in FIG. 12(a). You can see that: the first term from the top of the Hamiltonian H illustrated in FIG. 12(a) is a compression candidate in a format of (S₁+S₂-1)²; and according to the first compression method judgment table 2T1, the compression method is a “1-in-2-pieces selection problem” and is compressible. Moreover, variables S₁ and S₂ are variables which belong to the same group and, as illustrated in FIG. 12(b), the same variable group #1 is assigned to the variables S₁ and S₂, which are then stored in the variable group table 2T3.

Similarly, the second term from the top of the Hamiltonian H illustrated in FIG. 12(a) is a compression candidate in a format of (S₃+S₄-1)²; and according to the first compression method judgment table 2T1, you can see that the compression method is the “1-in-2-pieces selection problem” and is compressible. Moreover, variables S₃ and S₄ are variables which belong to the same group and, as illustrated in FIG. 12(b), the same variable group #2 is assigned to the variables S₃ and S₄, which are then stored in the variable group table 2T3.

Specifically speaking, as illustrated in FIG. 12(c), if the Hamiltonian H is expressed with a matrix M3 which has the variables S₁ to S₄ in its rows and columns, you can see that the matrix M3 is divided into an area corresponding to a block B1 identified by the variable group #1 in the row direction and the variable group #1 in the column direction, and an area corresponding to a block B2 identified by the variable group #2 in the row direction and the variable group #2 in the column direction.

Then, the blocks B1 and B2 are compressed to parameters “N=2 and M=1,” so that the “compression method” and the “parameters” are associated with each other and are recorded in the divided information table 2T4.

When the above-described processing has been executed with respect to all the compression candidates in the former half processing of the compression processing, the former half processing of the compression processing terminates.

In this example, no spin variable which belongs to a plurality of variable group information does not exist. Specifically speaking, there is no overlapping part of the areas (blocks). However, the plurality of areas may overlap each other and any spin variable which belongs to the overlapping area is recognized as another variable group. For example, if an area to which S₁, S₂, S₃ belong is created and an area to which S₃, S₄ belong are created, the variable S₃ which belongs to the plurality of variable groups is recognized as belonging to an independent group and the matrix is divided by dividing the variables into different groups as follows: the variable group #1: S₁, S₂; the variable group #2: S₃; and the variable group #3: S₄.

### Latter Half Processing of Compression Processing According to Embodiment 1

FIG. 13 is a flowchart illustrating the latter half processing of the compression processing according to Embodiment 1. This flowchart illustrates a procedure for converting the constraint equation into the compression format corresponding to the “specific area.” The latter half processing of the compression processing is executed by the information processing system 2 following the former half processing of the compression processing.

This latter half processing is targeted at an area(s) which is not compressed by the former half processing of the compression processing (FIG. 11).

Firstly in step S121, the Hamiltonian compression format conversion unit 21 selects one of the compression candidates from the area(s) which is not compressed by the former half processing of the compression processing (FIG. 11). The compression candidate is a polynomial composed of at least some terms of the Hamiltonian. For example, a term which has not been compressed may be selected as the compression candidate sequentially on a term basis, starting from the top term of the Hamiltonian.

Next, in step S122, the Hamiltonian compression format conversion unit 21 refers to the second compression method judgment table 2T2 and judges whether the compression candidate selected in step S121 is compressible or not, that is, whether it corresponds to any one of the compressible conditions in the second compression method judgment table 2T2 or not. If the compression candidate is compressible (step S122: YES), the Hamiltonian compression format conversion unit 21 proceeds to processing in step S123; and if the compression candidate is not compressible (step S122: NO), the Hamiltonian compression format conversion unit 21 proceeds to processing in step S125. If the compression candidate selected in step S121 matches the plurality of compressible conditions in the second compression method judgment table 2T2, a specified selection rule, for example, to prioritize an entry close to the top of the second compression method judgment table 2T2 is set so that one compression method will be selected.

In step S123, the Hamiltonian compression format conversion unit 21 stores a variable(s) which has not been stored, among variables (spins) included in the compression candidate(s) and judged as being compressible in step S122, in the variable group table 2T3. Incidentally, it is assumed that the variables included in a plurality of compression candidates which are judged as being compressible in step S122 belong to an independent variable group.

Next, in step S124, the Hamiltonian compression format conversion unit 21 stores the compression method and parameters corresponding to the compressible condition of the compression candidate, which was judged as being compressible in step S122, in the divided information table 2T4.

Then, in step S125, the Hamiltonian compression format conversion unit 21 judges whether all the compression candidates have been checked or not. If all the compression candidates have been checked (step S125: YES), the Hamiltonian compression format conversion unit 21 terminates this latter half processing; and if any unchecked compression candidate exists (step S125: NO), the Hamiltonian compression format conversion unit 21 returns to the processing in step S121.

### Input and Output of Latter Half Processing of Compression Processing According to Embodiment 1

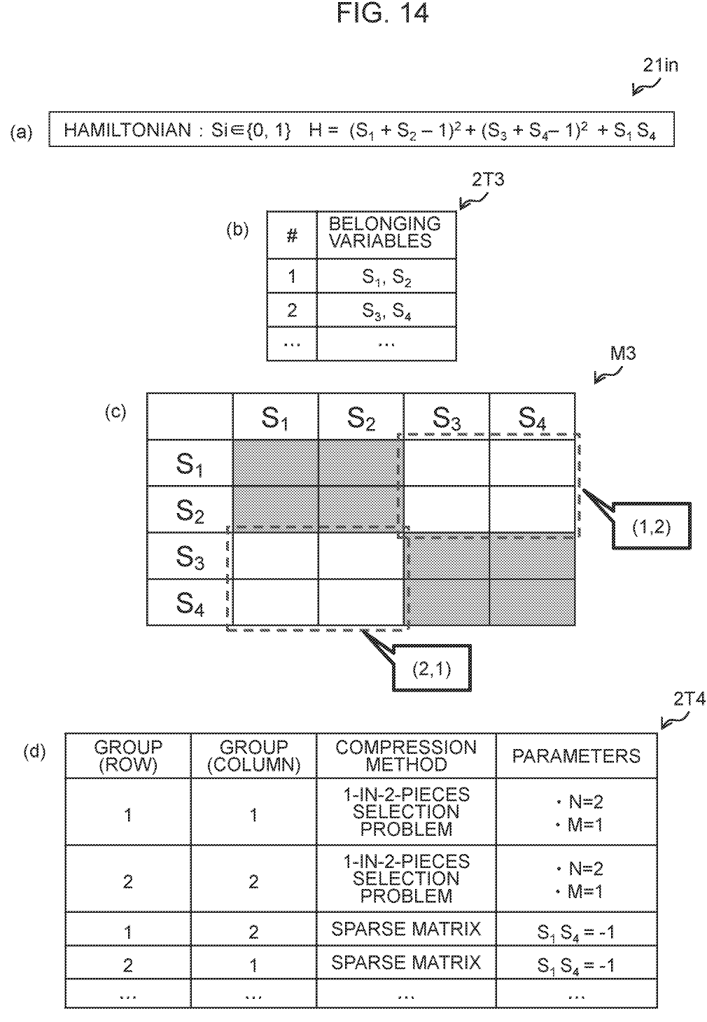

FIG. 14 is a diagram illustrating input and output of the latter half processing of the compression processing according to Embodiment 1. For example, regarding an area(s) which is/are not compressed by the former half processing of the compression processing (FIG. 11), a term which is not compressed by the former half processing of the compression processing in the Hamiltonian (constraint equation) 21in in FIG. 14(a) is S₁S₄. Referring to the variable group table 2T3 regarding S₁S₄, S₁ is the group (row) #1 =1 and S₄ is the group (column) #1 =2 ((1, 2) in FIG. 14(c)) or S₁ is the group (column) #1 =1 and S₄ is the group (row) #1 =4 ((2, 1) in FIG. 14(c)) in the matrix M3. Also, in (group (row), group (column)) = (1, 2) and (2, 1), the number of non-zero elements is 1 out of the total number of elements, which is 4, that is, less than ⅓, so that a matrix of (group (row), group (column)) = (1, 2) and (2, 1) becomes a “sparse matrix” with the element value = -1 .

Therefore, as illustrated in FIG. 14(d), information of the compression method for the matrix of (group (row), group (column)) ₌ (1, 2) and (2, 1) which is the “sparse matrix” and the parameter “-1” is recorded in the divided information table 2T4. Incidentally, the matrix of (group (row), group (column)) = (1, 2) may be recorded as a target matrix of (group (row), group (column)) = (2, 1). Alternatively, the matrix of (group (row), group (column)) = (2, 1) may be recorded as a target matrix of (group (row), group (column)) = (1, 2).

When the above-described processing has been executed with respect to all the compression candidates in the latter half processing of the compression processing, the latter half processing of the compression processing terminates.

In this embodiment, the order of an n(n≥3)- order Hamiltonian H (S₁, ..., S_{N}) is lowered by adding the spin(s) to obtain H'(S₁, ..., S_{N}) which is a quadratic expression of the variable S₁, ..., S_{N}. A matrix in the format of the matrix M3 illustrated in FIG. 12 and FIG. 14 is created by using SᵢSⱼ(i≠j) as a coefficient and paying attention to Sᵢ²=1(i=1, 2, ..., N). If this matrix M3 or a block(s) obtained by dividing the matrix M3 corresponds to the aforementioned “specific problem” or “specific area,” the block is compressed to the corresponding compression format.

Most of Hamiltonians for real problems can be expressed by any one of, or a combination of, the “M-in-N-pieces selection problem,” the “N-rook problem,” the “traveling salesman problem,” the “zero matrix,” the “constant matrix,” the “sparse matrix,” and the “transposed matrix” as mentioned earlier. Therefore, by compressing the block obtained by dividing the matrix which represents the Hamiltonian in the compression format corresponding to the “specific problem” or the “specific area,” it is possible to reduce the memory capacity when storing the real problem(s) in the memory and realize efficient memory consumption.

### Matrix Calculation Processing Using Compression Format According to Embodiment 1

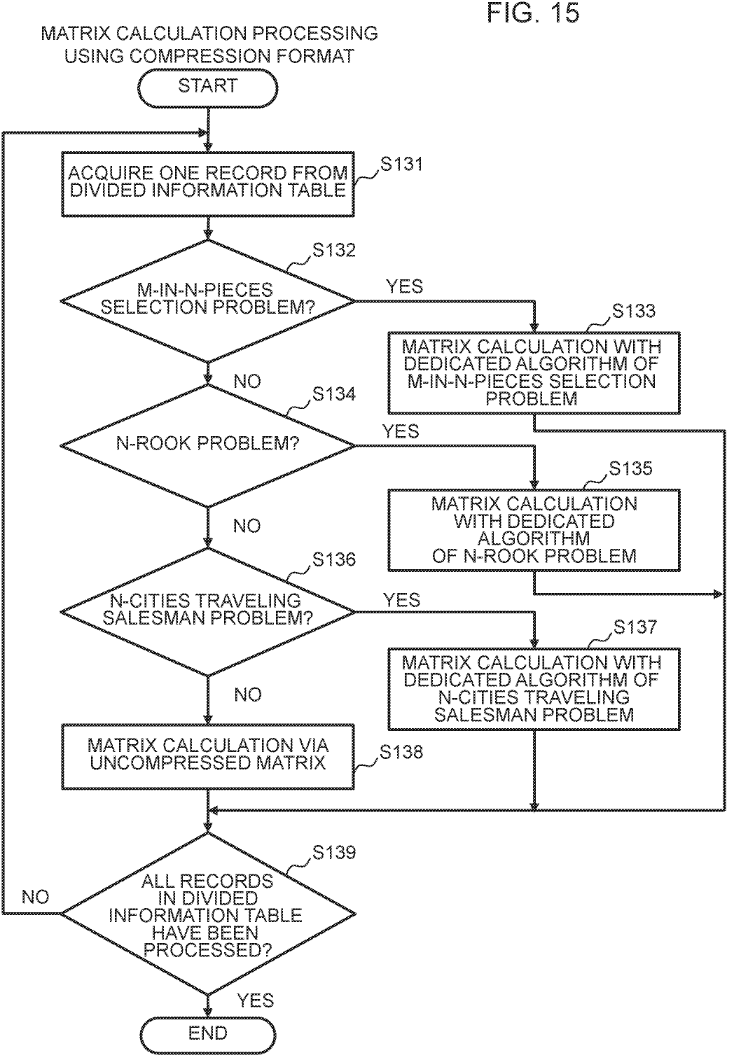

FIG. 15 is a flowchart illustrating matrix calculation processing using the compression format according to Embodiment 1. The matrix calculation processing using the compression format is executed by the information processing system 2 following the latter half processing of the compression processing.

Firstly in step S131, the compression format calculation unit 22 (FIG. 5) acquires one record from the divided information table 2T4. Next, in step S132, the compression format calculation unit 22 judges whether the record selected in step S131 is the “M-in-N-pieces selection problem” or not. If the record selected in step S131 is the “M-inN-pieces selection problem” (step S132: YES), the compression format calculation unit 22 proceeds to processing in step S133; and if the record selected in step S131 is other than the “M-in-N-pieces selection problem” (step S132: NO), the compression format calculation unit 22 proceeds to processing in step S134. In step S133, the compression format calculation unit 22 executes the matrix calculation according to a dedicated algorithm for the “M-in-N-pieces selection problem.”

In step S134, the compression format calculation unit 22 judges whether the record selected in step S131 is the “N-rook problem” or not. If the record selected in step S131 is the “N-rook problem” (step S134: YES), the compression format calculation unit 22 proceeds to processing in step S135; and if the record selected in step S131 is other than the “N-rook problem” (step S134: NO), the compression format calculation unit 22 proceeds to processing in step S136. In step S135, the compression format calculation unit 22 executes the matrix calculation according to a dedicated algorithm for the “N-rook problem”.

In step S136, the compression format calculation unit 22 judges whether the record selected in step S131 is the “N-cities traveling salesman problem” or not. If the record selected in step S131 is the “N-cities traveling salesman problem” (step S136: YES), the compression format calculation unit 22 proceeds to processing in step S137; and if the record selected in step S131 is other than the “N-cities traveling salesman problem” (step S136: NO), the compression format calculation unit 22 proceeds to processing in step S138. In step S137, the compression format calculation unit 22 executes the matrix calculation according to a dedicated algorithm for the “N-cities traveling salesman problem.”

In step S138, the record selected in step S131 is the “specific area” such as the “zero matrix,” the “constant matrix,” the “sparse matrix,” or the “transposed matrix,” the compression format calculation unit 22 executes the matrix calculation by using a non-compression matrix without using the compression format.

Lastly, in step S139, the compression format calculation unit 22 judges whether all the records in the divided information table 2T4 have been processed or not. If all the records in the divided information table 2T4 have been processed (step S139: YES), the compression format calculation unit 22 terminates this matrix calculation processing; and if not all the records in the divided information table 2T4 have been processed (step S139: NO), the compression format calculation unit 22 returns to the processing in step S131.

Incidentally, the Hamiltonian constraint equation is not limited to the examples illustrated in this embodiment and other description methods capable of expressing the compression may be used.

In Embodiment 1, the information processing system 2 includes the Hamiltonian compression format conversion unit 21 and the compression format calculation unit 22 executes the pseudo-annealing in the compression format obtained by the compression of the input Hamiltonian constraint equation by the Hamiltonian compression format conversion unit 21. However, without limitation to this example, the information processing system 2 may not include the Hamiltonian compression format conversion unit 21 and the compression format calculation unit 22 may execute the pseudo-annealing by inputting the compression format which was compressed in advance in the same manner as the Hamiltonian compression format conversion unit 21.

### Embodiment 2

An explanation will be provided below about Embodiment 2 in which a matrix of an input Hamiltonian is converted into a compression format thereby expressing the Hamiltonian with a smaller information volume than that of the matrix and reducing the memory capacity to store the information. Regarding Embodiment 2, the differences from Embodiment 1 will be mainly explained and an explanation about the same or similar matters will be omitted as necessary.

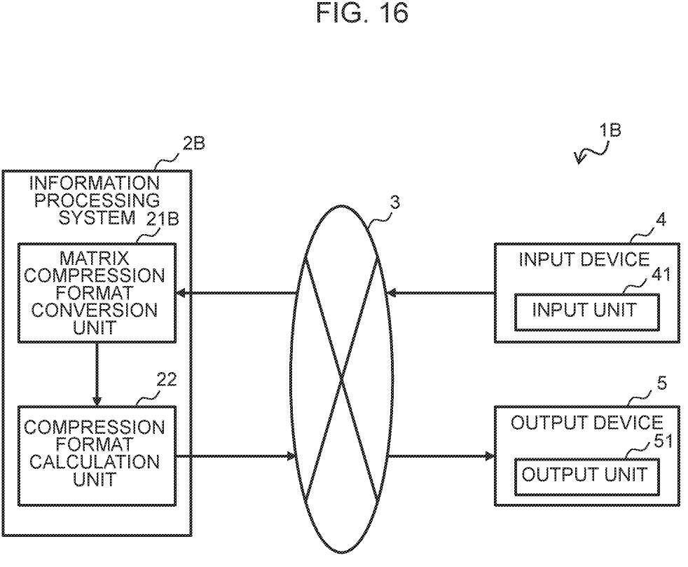

FIG. 16 is a diagram illustrating the configuration of the entire system 1B according to Embodiment 2. The entire system 1B has an information processing system 2B instead of the information processing system 2 as compared to the entire system 1 according to Embodiment 1. The information processing system 2B has a matrix compression format conversion unit 21B instead of the Hamiltonian compression format conversion unit 21 as compared to the information processing system 2 according to Embodiment 1.

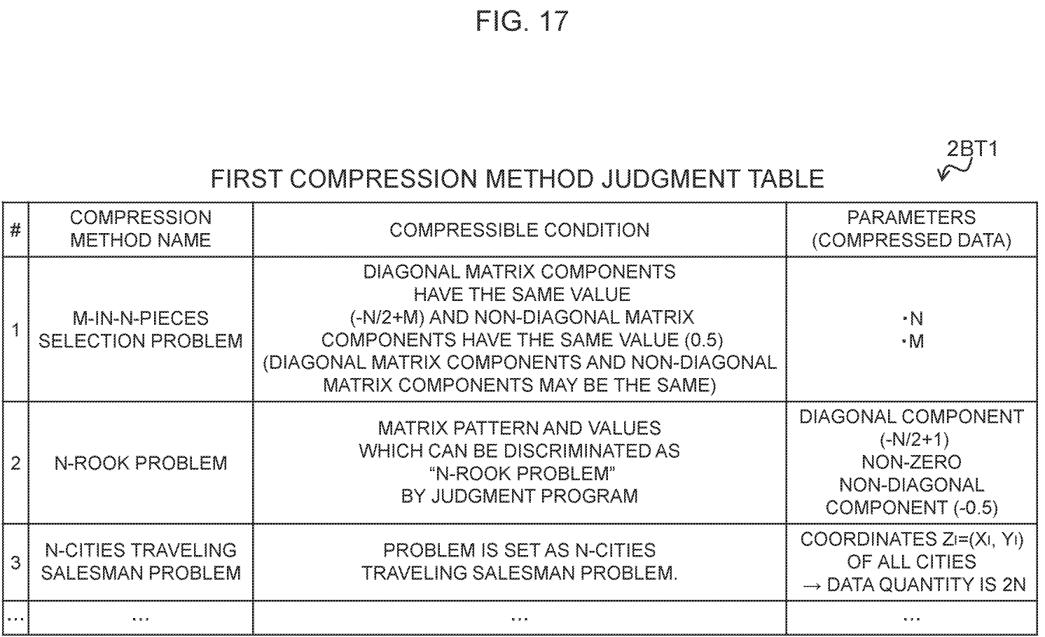

Furthermore, the information processing system 2B retains a first compression method judgment table 2BT1 (FIG. 17) in a specified storage area (which is not illustrated in the drawing) instead of the first compression method judgment table 2T1 (FIG. 6) according to Embodiment 1.

When compressing the Hamiltonian matrix which is input via the input unit 41 for the input device 4, the matrix compression format conversion unit 21B judges the compression method by referring to the first compression method judgment table 2BT1 and the second compression method judgment table 2T2. Then, the matrix compression format conversion unit 21B converts the Hamiltonian into the compression format (compressed data) according to the judged compression method. The details of the processing of the matrix compression format conversion unit 21B will be described later.

### First Compression Method Judgment Table 2BT1 According to Embodiment 2

FIG. 17 is a diagram illustrating the first compression method judgment table 2BT1 according to Embodiment 2.

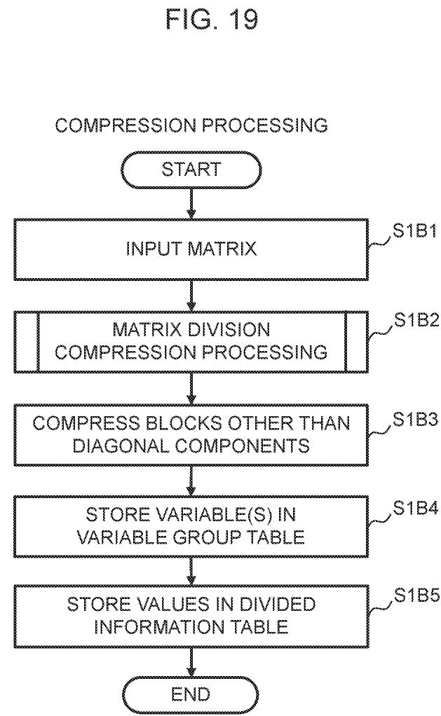

The first compression method judgment table 2BT1 according to Embodiment 2 is a table for judging the compression method for the input Hamiltonian matrix and has columns of a compression method name, a compressible condition, and parameters. When executing the former half processing of compression processing (FIG. 19) according to Embodiment 2, the matrix compression format conversion unit 21B (FIG. 16) refers to the first compression method judgment table 2BT1 and compresses the input Hamiltonian matrix or a block(s) obtained by dividing this matrix into a parameter(s) (compressed data) of the compression method corresponding to the relevant compressible condition.

For example, if the matrix compression format conversion unit 21B judges that regarding the input Hamiltonian matrix or the block obtained by dividing this matrix, diagonal components are of a pattern and values of the same value (=-N/2+M) and non-diagonal components are of a pattern and values of the same value (=-0.5), the matrix compression format conversion unit 21B recognizes, from the entry #1 of the first compression method judgment table 2BT1, that this area corresponds to the compression method name “M-in-N-pieces selection problem.” The area herein used means the input Hamiltonian matrix or the block obtained by dividing this matrix. Then, the matrix compression format conversion unit 21B compresses the relevant area of the input Hamiltonian matrix into the parameters “N and M.” Incidentally, the compression parameters may be set as the diagonal component =-N/2+M and the non-diagonal component =-0.5.

Furthermore, for example, if it is judged by a specified judgment program that the input Hamiltonian matrix or the block obtained by dividing this matrix corresponds to the “N-rook problem,” the matrix compression format conversion unit 21B compresses the relevant area of the input Hamiltonian to the diagonal components =-N/2+M and the non-zero non-diagonal component =-0.5.

Furthermore, for example, if it is judged by the specified judgment program that the input Hamiltonian matrix or the block obtained by dividing this matrix corresponds to the “N-cities traveling salesman problem,” the matrix compression format conversion unit 21B compresses the relevant area of the input Hamiltonian into the coordinates Zᵢ=(Xᵢ, Yᵢ) (i=1, 2, ..., N) of all the N cities.

### Entire Processing of Embodiment 2

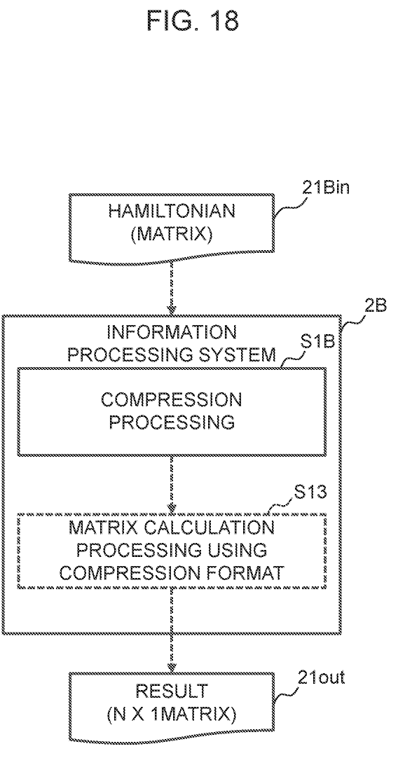

FIG. 18 is a flowchart illustrating the entire processing of Embodiment 2. The entire processing of Embodiment 2 inputs a Hamiltonian (matrix) 21Bin and outputs the result (N×1 matrix) 21 out as illustrated in FIG. 16. The entire processing of Embodiment 2 includes compression processing S1B instead of the compression processing S1 as compared to the entire processing of Embodiment 1 (FIG. 10).

### Former Half Processing of Compression Processing According to Embodiment 2

FIG. 19 is a flowchart illustrating the compression processing S1B according to Embodiment 2. This flowchart illustrates a procedure for converting the block including diagonal components in the Hamiltonian matrix into the compression format corresponding to the “specific problem.”

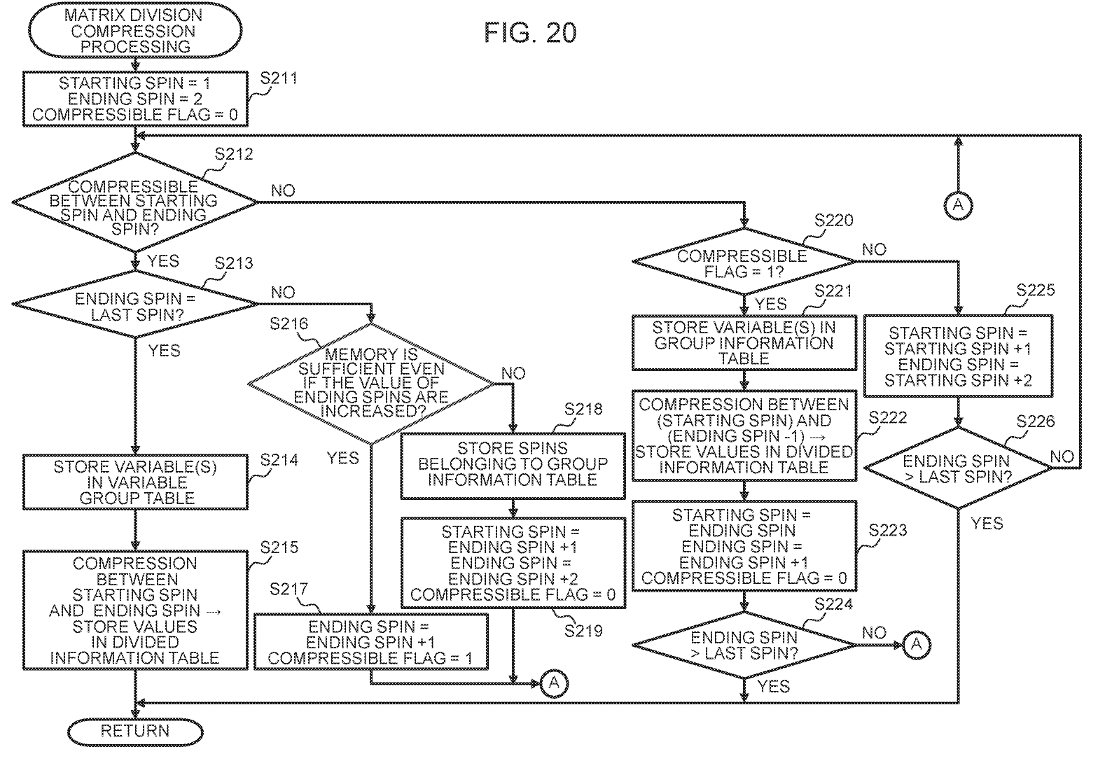

Firstly, in step S1B1, the matrix compression format conversion unit 21B1 accepts the input of the Hamiltonian matrix. Next, in step S1B2, the matrix compression format conversion unit 21B1 divides the matrix, the input of which was accepted in step S1B1, at positions suited for the compression, and compresses each block (matrix division compression processing). In step S1B2, the block(s) including the diagonal components of the matrix, the input of which was accepted in step S1B1. The details of the matrix division compression processing will be described later with reference to FIG. 20.

Next, in step S1B3, the matrix compression format conversion unit 21B1 refers to the second compression method judgment table 2T2 (FIG. 7) and compresses a block(s) other than the block(s) including the diagonal components of the matrix divided in step S11B2. Specifically speaking, the matrix compression format conversion unit 21B1 judges whether or not the block(s) other than the block(s) including the diagonal components corresponds to any one of the compressible conditions in the second compression method judgment table 2T2, and compresses it/them to the corresponding parameters.

Then, in step S1B4, the matrix compression format conversion unit 21B1 stores a spin(s) which has not been stored, among the spins included in all the blocks compressed in step S1B3, in the variable group table 2T3. Incidentally, it is assumed that a variable(s) included in the plurality of blocks which were judged as being compressible in step S1B3 belongs to the independent variable group.

Subsequently, in step S124, the matrix compression format conversion unit 21B1 stores the compression method and the compressed data (the parameters) corresponding to the compressible condition of the block(s), which was judged as being compressible in step S1B3, in the divided information table 2T4.

### Divided Position Deciding Processing of Compression Processing According to Embodiment 2

FIG. 20 is a flowchart illustrating divided position deciding processing (step S1B2) of the compression processing according to Embodiment 2. The matrix which is a processing target of this divided position deciding processing is a square matrix in which spins are aligned in ascending order of indexes in each of the row direction and the column direction.

Firstly, in step S211, the matrix compression format conversion unit 21B1 initializes a starting spin and an ending spin, which are variables, to 1 and 2, respectively, and a compressible flag to 0. The starting spin indicates the position of a starting matrix element in the row direction and in the column direction and the ending spin indicates the position of an ending matrix element in the row direction and in the column direction.

Next, in step S212, the matrix compression format conversion unit 21B1 refers to the first compression method judgment table 2BT1 and judges whether or not a block diagonal matrix (partial square matrix) defined by the starting spin and the ending spin, which are currently set, and obtained by dividing the matrix, which is the processing target of the divided position deciding processing corresponds to the compressible condition (compressible). The block diagonal matrix is a block including the diagonal components of the matrix before the division. If the block diagonal matrix defined by the starting spin and the ending spin, which are currently set, is compressible (step S212: YES), the matrix compression format conversion unit 21B1 proceeds to processing in step S213; and if the block diagonal matrix defined by the starting spin and the ending spin, which are currently set, is not compressible (step S212: NO), the matrix compression format conversion unit 21B1 proceeds to processing in step S220.

In step S213, the matrix compression format conversion unit 21B1 judges whether or not the aforementioned ending spin is the last spin of the matrix which is the processing target. If the ending spin is the last spin (step S213: YES), the matrix compression format conversion unit 21B1 proceeds to processing in step S214; and if the ending spin is not the last spin (step S213: NO), the matrix compression format conversion unit 21B1 proceeds to processing in step S216.

In step S214, the matrix compression format conversion unit 21B1 stores, in the variable group table 2T3, spins included in the block diagonal matrix of the matrix defined by the starting spin and the ending spin, which are currently set.

Next, in step S215, the matrix compression format conversion unit 21B1 stores, in the divided information table 2T4, the compression method and the parameters corresponding to the compressible condition satisfied by the block diagonal matrix defined by the current starting spin and ending spin in the first compression method judgment table 2T1.

In step S216, the matrix compression format conversion unit 21B1 judges whether or not the memory is sufficient even if the ending spin is increased (that is, whether or not the memory capacity capable of continuing this processing can be secured). If the memory is sufficient even if the ending spin is increased (step S216: YES), the matrix compression format conversion unit 21B1 proceeds to processing in step S217; and if the memory becomes insufficient if the ending spin is increased (step S216: NO), the matrix compression format conversion unit 21B1 proceeds to processing in step S218.

In step S217, the matrix compression format conversion unit 21B1 adds 1 to the ending spin, which is variable, and sets 1 to the compressible flag. If step S217 terminates, the matrix compression format conversion unit 21B1 returns to the processing in step S212.

In step S218, the matrix compression format conversion unit 21B1 stores spins, which are included in the block diagonal matrix defined by the current starting spin and ending spin, in the variable group table 2T3.

Next, in step S219, the matrix compression format conversion unit 21B1 sets a value obtained by adding 1 to the ending spin, to the starting spin, adds 2 to the ending spin, sets 0 to the compressible flag. If step S219 terminates, the matrix compression format conversion unit 21B1 returns to the processing in step S212.

On the other hand, in step S220, the matrix compression format conversion unit 21B1 judges whether the compressible flag =1 or not. If the compressible flag =1 (step S220: YES), the matrix compression format conversion unit 21B1 proceeds to processing in step S221; and if the compressible flag ≠1 (step S220: NO), the matrix compression format conversion unit 21B1 proceeds to the processing in step S225.

In step S221, the matrix compression format conversion unit 21B1 stores spins, which are included in the block diagonal matrix defined by the current starting spin and ending spin, in the variable group table 2T3. Next, in step S222, the matrix compression format conversion unit 21B1 stores, in the divided information table 2T4, the compression method and the parameters corresponding to the compressible condition satisfied by the block diagonal matrix defined by the current starting spin and (the ending spin -1) in the first compression method judgment table 2T1.

Then, in step S223, the matrix compression format conversion unit 21B1 sets the ending spin to the starting spin, adds 1 to the ending spin, and sets 0 to the compressible flag. In this processing, the block diagonal matrix adjacent to the block which was the last processing target is selected. Subsequently, in step S224, the matrix compression format conversion unit 21B1 judges whether the relation of the ending spin > the last spin is established or not. If the relation of the ending spin > the last spin is established (step S224: YES), the matrix compression format conversion unit 21B1 terminates this matrix division compression processing; and if the relation of the ending spin ≤ the last spin is established (step S224: NO), the matrix compression format conversion unit 21B1 proceeds to the processing in step S212.

In step S225, the matrix compression format conversion unit 21B1 adds 1 to the starting spin and adds 2 to the ending spin. Next, in step S226, the matrix compression format conversion unit 21B1 checks whether the relation of the ending spin > the last spin is established or not. If the relation of the ending spin > the last spin is established (step S226: YES), the matrix compression format conversion unit 21B1 terminates this matrix division compression processing; and if the relation of the ending spin ≤ the last spin is established (step S226: NO), the matrix compression format conversion unit 21B1 proceeds to the processing in step S212.

In this divided position deciding processing, the matrix which is the processing target is divided into one or more block diagonal matrixes which include a maximum of diagonal components successively aligned in this matrix and satisfy the compressible condition of the first compression method judgment table 2BT1 (FIG. 17), and a block matrix other than the block diagonal matrix(es) of the matrix divided along division lines used when dividing this matrix into the block diagonal matrix(es). Then, the block diagonal matrix obtained by dividing the matrix is compressed into the compression format by means of the compression technology corresponding to the compressible condition.

In this divided position deciding processing, the compression area is controlled by only the compression flag which takes the values of 0 and 1; however, the processing may be processing in consideration of a processing speed of calculation by using the compression format. Specifically, the compression format in which the last compression area was compressed is stored in the compressible flag; and if the compression format capable of compressing the current compression area is different from the compression format capable of compressing the last compression area, the matrix is divided at the last compression area and the compression is carried out.

### Explanation of Matrix Division According to Embodiment 2

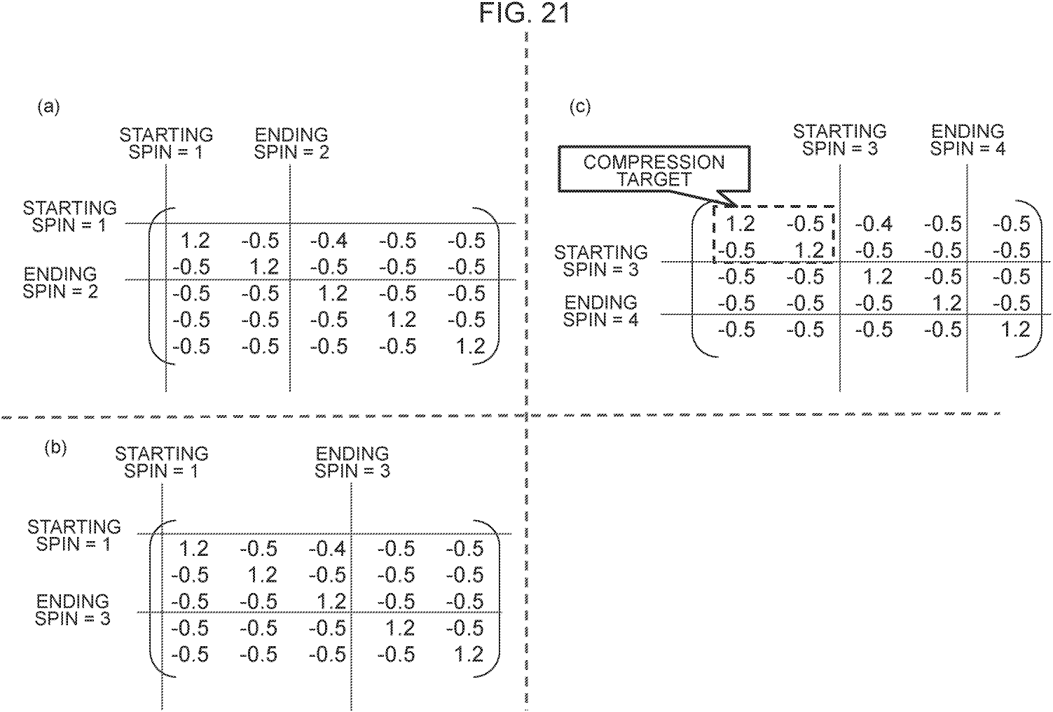

FIG. 21 is a diagram for explaining matrix division according to Embodiment 2. FIG. 21 shows an example of dividing a quintic matrix and its last spin is 5.

FIG. 21(a) illustrates a block in which the starting spin =1 and the ending spin =2 are set in step S211 in FIG. 20. FIG. 21 (b) illustrates a state where it is judged in step S213 in FIG. 20 that the ending spin ≠ the last spin; and since it is judged in step S216 that the ending pin can be increased, so that the ending spin is increased by 1 in step S217 and the compressible flag = 1 is set.

However, a block of the starting spin = 1 and the ending spin = 3 in FIG. 21 (b) is not compressible (step S212: NO) and the compressible flag = 1 is set (that is, the block which was the judgment target last time was compressible). Consequently, as illustrated in FIG. 21 (c), the block of the starting spin = 1 and the ending spin = 2 is compressed in steps S221 and S222. Then, as illustrated in FIG. 21 (c), the ending spin is set to the starting spin and one is added to the ending spin in step S223, so that the next compression judgment target block will have the starting spin = 3 and the ending spin = 4.

In the aforementioned Embodiments 1 and 2, the Hamiltonian constraint equation or the Hamiltonian matrix is input to the information processing system 2, 2B and information obtained by extracting the feature quantity of the constraint equation is stored, as the compression format, in the memory. By preparing a dedicated algorithm for this compression format and performing the annealing processing, the input information volume and the memory amount upon calculation can be reduced as compared to the case where the Hamiltonian is decompressed as a matrix in the memory.

### Configuration of Computer 500 for Implementing Information Processing System 2

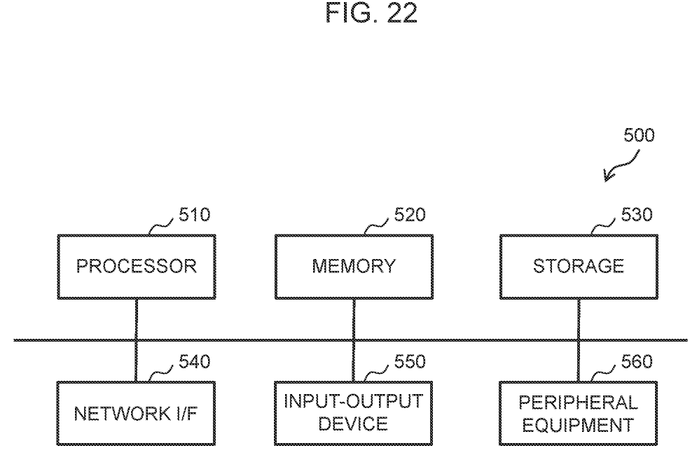

FIG. 22 is a diagram illustrating a configuration example of a computer 500 for implementing the information processing system 2. In the computer 500, a processor 510, a memory 520 such a RAM (Random Access Memory), storage 530 such as an SSD (Solid State Drive) and/or an HDD (Hard Disk Drive), and a network I/F (Inter/Face) 540 are connected via a bus.

In the computer 500, the information processing system 2 is implemented by reading programs for implementing the information processing system 2 from the storage 530 and having them executed by the processor 510 and the memory 520 in cooperation with each other. Alternatively, the programs for implementing the information processing system 2 may be acquired from an external computer equipped with a non-transitory storage device through communications via the network I/F 540. Alternatively, the programs for implementing the information processing system 2 may be recorded in a non-transitory recording medium and read by a medium reading device.

The processor 510 is one example of the processing unit for the information processing system 2 for executing various kinds of processing in cooperation with the memory. Moreover, the Hamiltonian compression format conversion unit 21 and the compression format calculation unit 22 (FIG. 5) may be integrated into one processing unit or may be distributed as different processing units. Furthermore, the Hamiltonian compression format conversion unit 21 and the compression format calculation unit 22 may be mounted in one information processing system 2 or may be mounted in different information processing systems.

Similarly, the matrix compression format conversion unit 21B and the compression format calculation unit 22 (FIG. 16) may be integrated into one processing unit or may be distributed as different processing units. Moreover, the matrix compression format conversion unit 21B and the compression format calculation unit 22 may be mounted in one information processing system 2B or may be mounted in different information processing systems.

The present invention is not limited to the aforementioned embodiments, but includes various variations. For example, the aforementioned embodiments have been described in detail in order to explain the present invention in an easily comprehensible manner and are not necessarily limited to those having all the configurations explained above. Furthermore, unless any contradiction occurs, part of the configuration of a certain embodiment can be replaced with the configuration of another embodiment and the configuration of another embodiment can be added to the configuration of a certain embodiment. Also, regarding part of the configuration of each embodiment, it is possible to add, delete, replace, integrate, or distribute the configuration. Furthermore, the configurations and processing indicated in the embodiments can be distributed, integrated, or replaced as appropriate on the basis of processing efficiency or implementation efficiency.

1. An information processing method executed by an information processing system for executing an optimum solution search for an optimization problem,
wherein the information processing system includes:
a processing unit that executes processing in cooperation with a memory; and a
storage unit that stores a compression technology for a data volume to be applied to a Hamiltonian of the optimization problem, a compressible condition indicating whether the compression technology can be applied or not, and compression method judgment information associated with a compression format indicating a feature quantity of the Hamiltonian when the Hamiltonian is compressed by applying the compression technology; and
wherein the processing unit:
refers to the compression method judgment information and judges a part included in the Hamiltonian which satisfies the compressible condition; and
extracts the feature quantity of the part, which is included in the Hamiltonian and judged as satisfying the compressible condition, by means of the compression technology corresponding to the compressible condition and compresses the extracted feature quantity into the compression format.

2. The information processing method according to claim 1,
wherein the Hamiltonian is a quadratic constraint equation; and
wherein if a quadratic term included in the constraint equation satisfies the compressible condition, the processing unit compresses the quadratic term into the compression format by means of the compression technology corresponding to the compressible condition.

3. The information processing method according to claim 2,
wherein if the constraint equation is of a cubic or higher order, the processing unit lowers a degree of the constraint equation to a quadratic degree and then generates a lowered-order constraint equation; and
if a quadratic term included in the lowered-degree constraint equation satisfies the compressible condition, the processing unit compresses the quadratic term into the compression format by means of the compression technology corresponding to the compressible condition.

4. The information processing method according to claim 1,
wherein the Hamiltonian is a matrix; and
wherein if a block matric which is a part obtained by dividing the matrix satisfies the compressible condition, the processing unit compresses the block matrix into the compression format by means of the compression technology corresponding to the compressible condition.

5. The information processing method according to claim 4,
wherein the processing unit:
divides the matrix into one or more block diagonal matrixes, each of which includes a maximum of diagonal components successively aligned in the matrix and satisfies the compressible condition, and a block matrix other than the block diagonal matrix or matrixes of the matrix divided along division lines used when dividing the matrix into the block diagonal matrix or matrixes; and
compresses the block diagonal matrix or matrixes and the block matrix which are obtained by dividing the matrix into the compression format by means of the compression technology corresponding to the compressible condition.

6. The information processing method according to claim 1,
wherein the processing unit judges whether the part included in the Hamiltonian satisfies the compressible condition or not on the basis of whether or not the part can be applied to a specified formulation condition, or by a specified algorithm.

7. The information processing method according to claim 1,
wherein the compression technology is a technology for replacing the part included in the Hamiltonian with any one of parameters, that is, an M-in-N-pieces selection problem for selecting M pieces from N pieces, an N-rook problem for placing N pieces of rooks in matrix squares in a state of mutually having no power of move, an N-cities traveling salesman problem for visiting N cities, each city only once, in a shortest distance, a zero matrix, a constant matrix, a sparse matrix, and a transposed matrix.

8. The information processing method according to claim 1,
wherein the processing unit:
stores the compressed compression format in the memory; and
executes the optimum solution search for the optimization problem by processing the compression format, which is stored in the memory and obtained by means of the compression technology, by using an algorithm corresponding to the compression technology.

9. An information processing system for executing an optimum solution search for an optimization problem,
the information processing system comprising:
a processing unit that executes processing in cooperation with a memory; and a
storage unit that stores a compression technology for a data volume to be applied to a Hamiltonian of the optimization problem, a compressible condition indicating whether the compression technology can be applied or not, and compression method judgment information [symbol] associated with a compression format indicating a feature quantity of the Hamiltonian when the Hamiltonian is compressed by applying the compression technology; and
wherein the processing unit:
refers to the compression method judgment information and judges a part included in the Hamiltonian which satisfies the compressible condition; and
extracts the feature quantity of the part, which is included in the Hamiltonian and judged as satisfying the compressible condition, by means of the compression technology corresponding to the compressible condition and compresses the extracted feature quantity into the compression format.

10. The information processing system according to claim 9,
wherein the Hamiltonian is a quadratic constraint equation; and
wherein if a quadratic term included in the constraint equation satisfies the compressible condition, the processing unit compresses the quadratic term into the compression format by means of the compression technology corresponding to the compressible condition.

11. The information processing system according to claim 9,
wherein the Hamiltonian is a matrix; and
wherein if a block matric which is a part obtained by dividing the matrix satisfies the compressible condition, the processing unit compresses the block matrix into the compression format by means of the compression technology corresponding to the compressible condition.

12. The information processing system according to claim 11,
wherein the processing unit:
divides the matrix into one or more block diagonal matrixes, each of which includes a maximum of diagonal components successively aligned in the matrix and satisfies the compressible condition, and a block matrix other than the block diagonal matrix or matrixes of the matrix divided along division lines used when dividing the matrix into the block diagonal matrix or matrixes; and
compresses the block diagonal matrix or matrixes and the block matrix which are obtained by dividing the matrix into the compression format by means of the compression technology corresponding to the compressible condition.

13. The information processing system according to claim 9,
wherein the processing unit judges whether the part included in the Hamiltonian satisfies the compressible condition or not on the basis of whether or not the part can be applied to a specified formulation condition, or by a specified algorithm.

14. The information processing system according to claim 9,
wherein the compression technology is a technology for replacing the part included in the Hamiltonian with any one of parameters, that is, an M-in-N-pieces selection problem for selecting M pieces from N pieces, an N-rook problem for placing N pieces of rooks in matrix squares in a state of mutually having no power of move), an N-cities traveling salesman problem for visiting N cities, each city only once, in a shortest distance, a zero matrix, a constant matrix, a sparse matrix, and a transposed matrix.

15. An information processing program for causing a computer to function as the information processing system stated in claim 9.
